(19) United States
(12) Patent Application Publication
(10) Pub. No.: US 2004/0017302 A1
(43) Pub. Date: Jan. 29, 2004

(54) Matrix keyboard circuit for attenuating electromagnetic interference

(75) Inventor: Tsan-Fang Yu, Shulin City (TW)

Correspondence Address: BACON & THOMAS, PLLC, 625 SLATERS LANE, FOURTH FLOOR, ALEXANDRIA, VA, 22314

(73) Assignee: KYLINK COMMUNICATIONS CORP., Taipei (TW)

(21) Appl. No.: 10/200,120

(22) Filed: Jul. 23, 2002

(51) Int. Cl. H03M 11/00; H03K 17/94

(52) U.S. Cl. 341/22; 341/26

(57) ABSTRACT

The present invention provides to low noise and attenuate electromagnetic interference with a matrix keyboard circuit that the total number of key depend on the multiplication of N and M, (wherein “N” equals to the quantity of column unit and “M” equals to the quantity of row unit) and the intersection of every row and column connect to switch by ground signal. Keyboard normally open that the truth table of matrix Keyboard is logic “1”. When keyboard actuate the key that make a short circuit for row circuit, column circuit and ground signal, the truth table of matrix keyboard is logic “0”. Because of processor read the row and column signal, it may decode the signal for identification of the actuated key. The present invention provides a matrix keyboard circuit for general low-cost matrix keyboard, which employs a no scanning pulse signal to develop a matrix keyboard of low noise and attenuate electromagnetic interference.

### FIELD OF THE INVENTION

The present invention relates to a matrix keyboard circuit, particularly to a low noise and attenuate electromagnetic interference with a matrix keyboard circuit. Therefore, this invention can be employed to the keyboard of electrical products thereof; such as remote control, telephone, cybernation, electric medical treatment and avionic product etc.

### BACKGROUND OF THE INVENTION

To illustrate the advantage of matrix, the quantity of key for keyboard exceed in four. The matrix keyboard is designed to reduce the input and output elements and relative cost. Therefore, the matrix keyboard makes a wide application.

Referring to FIG. 1, it illustrates a traditional schematic view of matrix keyboard circuit. In general, the traditional matrix keyboard circuit sequentially adapts an output port to send pulse signal for scanning rows of matrix keyboard and an input port to receive column signal for actuated key, which can identify the actuated key by output port and input port signal refer to Truth Table of FIG. 1 to decode.

The matrix keyboard circuit requires scanning by periodic pulse signal for identification of actuated key (generally, the period of scanning is shorter than 20 ms). However, the periodic pulse signal easily brings high frequency harmonic waves that are cause of electromagnetic interference and noise of voice-frequency circuit. Thus, it may cause big problem in electrical product examination system.

### OBJECT OF THIS INVENTION

Therefore, the present invention provides a matrix keyboard circuit for attenuating electromagnetic interference with general low-cost matrix keyboard.

The main object of the present invention is to provide a low noise matrix keyboard.

Another object of the present invention is to provide a matrix keyboard for attenuating electromagnetic interference.

### SUMMERY OF THE INVENTION

A matrix keyboard circuit for identification of the actuated key, which comprises a first input port for reading a row signal, a second input port for reading a column signal; and a ground or a power supply signal positioning the intersection of said first input port and said second input port, wherein identification of the actuated key by said first input port and said second input port to refer to Table 1 to decode.

### BRIEF DESCRIPTION OF THE DRAWINGS

The present invention will be better understood from the following detailed description of preferred embodiments of the invention, taken in conjunction with the accompanying drawings, in which

FIG. 1 illustrates a traditional schematic view of matrix keyboard circuit;

FIG. 2 illustrates a schematic view of the present invention;

FIG. 3A˜FIG. 3B illustrate schematic view for application of the present invention;

FIG. 4A˜FIG. 4B illustrate preferred embodiment of the present invention; and

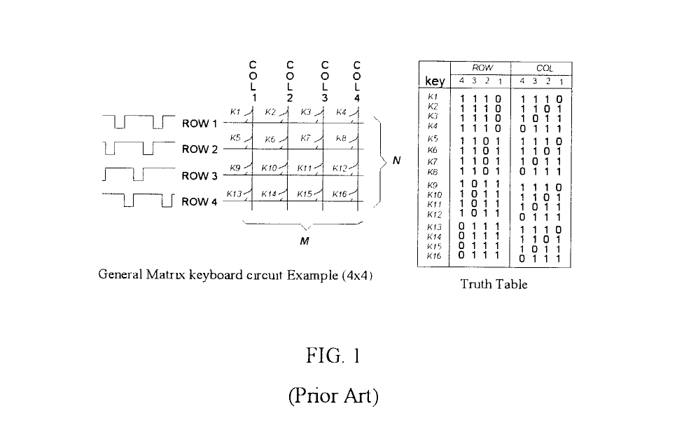

Table 1 illustrates a truth table for preferred embodiment of matrix keyboard circuit.

### DESCRIPTION OF THE PREFERRED EMBODIMENTS

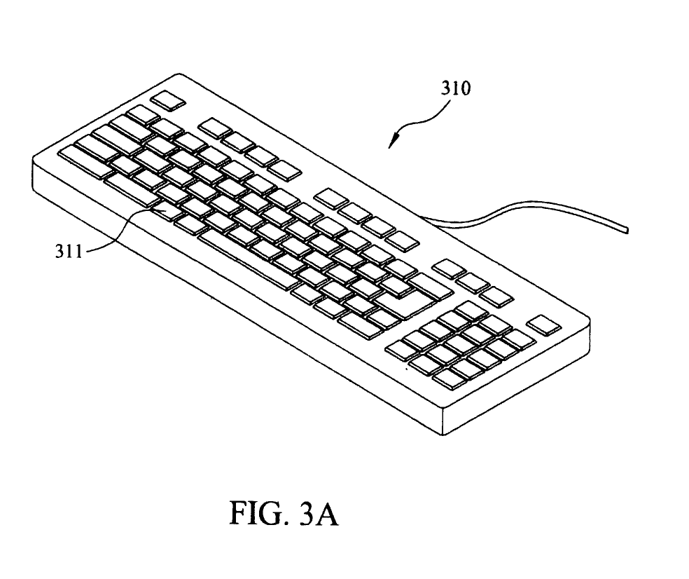

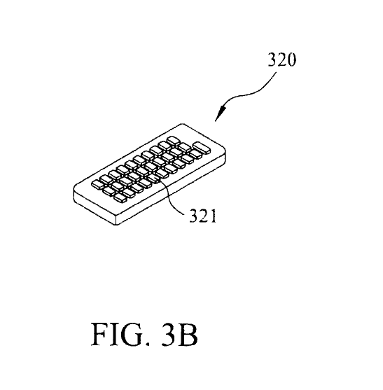

The following descriptions of the preferred embodiments are provided to understand the features and the structures of the present invention. The present invention provides a matrix keyboard circuit for attenuating electromagnetic interference. Please refer to the FIG. 3A for application of the present invention. The matrix keyboard includes a computer input keyboard 310 and a key 311. Please refer to the FIG. 3B for application of bank, which comprises a password input keyboard 320 and a key 321. FIG. 3A˜FIG. 3B illustrate schematic view for application of the present invention; but, the present invention may be embodied in other specific input keyboard without departing from the spirit of the essential attributes thereof; such as remote control, telephone, cybernation, electric medical treatment and avionic product etc.

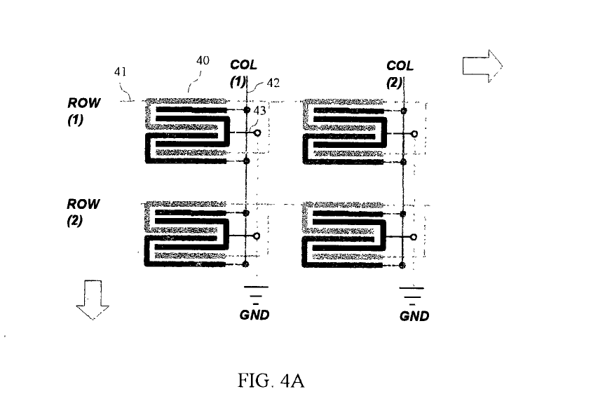

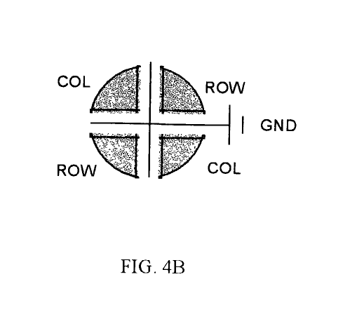

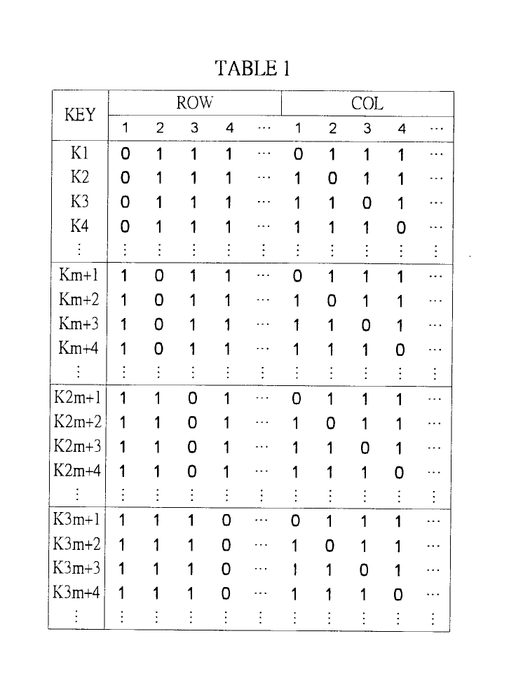

Referring to the FIG. 4A, we illustrate a matrix keyboard circuit for identification of the actuated key, which comprises a first input port 41 for reading a row signal, a second input port 42 for reading a column signal, and a ground signal 43 positioning the intersection of said first input port and said second input port, wherein identification of the actuated key by said first input port 41 and said second input port 42 to decode. We use three normally open contacts to form switch for FIG. 4A. Furthermore refer to FIG. 4B, printed circuit board and electric rubber conduction have be employed by matrix keyboard, moreover, the key pad has three electric contacts with simultaneous column signal, row signal and ground signal for printed circuit board. The matrix keyboard identified the actuated key by multiplication of column and row signal uses keyboard is at least four keys to develop clearly a cost down. Please refer to Table 1, it illustrates a truth table for preferred embodiment of matrix keyboard circuit. A said first input port 41 and a said second input port 42 connect to power supply by electric resistance respectively. Thus, the truth table of matrix keyboard is logic 1. The matrix keyboard circuit provided by this invention uses no pulse signal for avoiding high frequency harmonic waves.

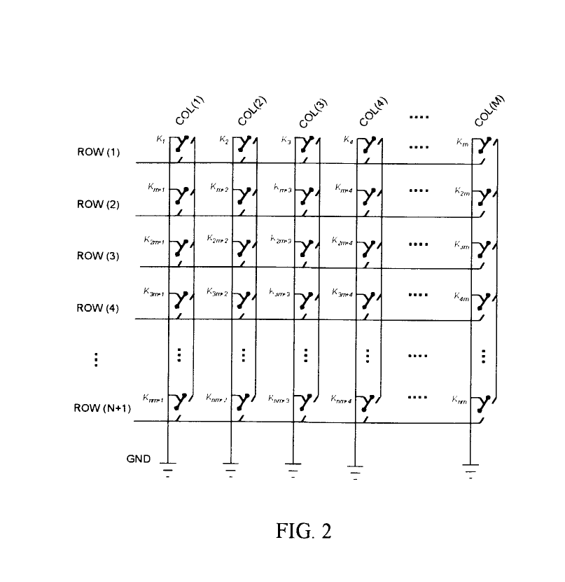

Referring to the FIG. 2, it illustrates a schematic view of the present invention that the total number of key depend on the multiplication of N and M, (wherein “N” equals to the quantity of column unit and “M” equals to the quantity of row unit) and the intersection of every row and column connect to switch by ground signal. Because of said first input port 41 and said second input port 42 connect to power supply by electric pull-high resistance respectively, which the truth table of matrix keyboard is logic 1. Actuate a key of the matrix keyboard circuit make a short circuit for said first input port 41, said second input port 42, and ground signal. Thus, the truth table of matrix keyboard is logic 0. Finally refer to Table 1, the processor uses identification of the actuated key by said first input port 41 and said second input port 42 to decode. The matrix keyboard circuit provided by this invention uses general low-cost matrix keyboard to develop attenuating electromagnetic interference. Therefore, the present invention is a reasonable perfection invention with feature of low noise and attenuating electromagnetic interference.

The present invention may be embodied in other specific forms without departing from the spirit of the essential attributes thereof; for example, said first input port 41 and said second input port 42 connect to ground by electric pull-down resistance respectively, and the intersection of each row and column connect to switch by power supply signal. Thus, the true table is completely reverse. Therefore, the illustrated embodiment should be considered in all respects as illustrative and not restrictive, reference being made to the appended claims rather than to the foregoing description to indicate the scope of the invention.

What is claimed is:

1. A matrix keyboard circuit for identification of the actuated key, which comprises:
a first input port for reading a row signal;
a second input port for reading a column signal; and
a ground or a power supply signal positioning the intersection of said first input port and said second input port;
wherein identification of the actuated key by said first input port and said second input port to decode.

2. The matrix keyboard circuit of claim 1, wherein said keyboard is at least four keys.
